(19) United States
(12) Patent Application Publication
(10) Pub. No.: US 2026/0358409 A1
(43) Pub. Date: Nov. 12, 2026

(54) SEMICONDUCTOR DIE CRACK DETECTION

(71) Applicant: Micron Technology, Inc., Boise, ID (US)

(72) Inventors: Chan H. Yoo, Boise, ID (US); Michael B. Morse, Boise, ID (US); Christopher D. Glancey, Boise, ID (US); Owen R. Fay, Meridian, ID (US)

(21) Appl. No.: 19/630,172

(22) Filed: Mar. 26, 2026

Related U.S. Application Data
(60) Provisional application No. 63/801,008, filed on May 6, 2025.

(51) Int. Cl. G01R 31/28; H10B 80/00

(52) U.S. Cl. CPC G01R 31/2884; H10B 80/00

(57) ABSTRACT

Methods, systems, and devices for semiconductor die crack detection are described. A memory system may detect crack propagation in a memory die from a front side and a back side of the memory die. The memory system may include a memory die, a first conductive path, and control circuitry. The memory die may include an array of memory cells at an array portion of the memory die. The first conductive path may extend from an upper surface of the memory die to a location past (e.g., below) a lower surface of the array portion of the memory die in a first direction. The memory system may transmit a first electrical signal via the first conductive path. Accordingly, the memory system may determine whether the memory die includes one or more defects based on whether the first conductive path maintains the single conductive path.

### CROSS REFERENCE

The present Application for Patent claims priority to U.S. Patent Application No. 63/801,008 by Yoo et al., entitled “SEMICONDUCTOR DIE CRACK DETECTION,” filed May 6, 2025, which is assigned to the assignee hereof, and which is expressly incorporated by reference in its entirety herein.

### TECHNICAL FIELD

The following relates to one or more systems for memory, including semiconductor die crack detection.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports semiconductor die crack detection in accordance with examples as disclosed herein.

FIGS. 2A-2C show an example of a memory die that supports semiconductor die crack detection in accordance with examples as disclosed herein.

FIG. 3 shows a block diagram of a memory system that supports semiconductor die crack detection in accordance with examples as disclosed herein.

FIG. 4 shows a flowchart illustrating a method or methods that support semiconductor die crack detection in accordance with examples as disclosed herein.

### DETAILED DESCRIPTION

Some memory systems may include rings (e.g., die rings) constructed on a circuitry side of a memory die (e.g., a front side of a die). These rings may detect and, in some cases inhibit, crack propagation from defects on the circuitry side of the die. However, some die manufacturing processes (e.g., thin die processing procedures) may include backside wafer grinding and backside wafer singulation processes. These processes may cause cracks to propagate from a back side of a memory die. In some cases, these cracks may bypass or otherwise avoid a ring structure of the memory die (e.g., due to the ring structure being on a surface of the memory die). Accordingly, techniques for detecting and preventing cracks within different portions of memory dies are desirable.

As described herein, a memory system may include one or more memory dies including a wall of one or more through silicon vias (TSVs) (e.g., full thick side wall, great wall of TSVs (FT-GWOT)) to form a crack ring around an edge (e.g., a boundary, a perimeter) of a memory die. The memory system may detect crack propagation in the memory die from both a front side and a back side of the memory die (e.g., by measuring electrical opens of a die ring daisy chain structure of the wall of TSVs). For example, a memory system may include a memory die, a first conductive path, and control circuitry. The memory die may include an array of memory cells at an array portion of the memory die. The first conductive path may extend from an upper surface of the memory die past a lower surface of the array portion of the memory die (and, in some cases, to a lower surface of the memory die). The memory system (e.g., via the control circuitry) may transmit a first electrical signal via the first conductive path. Accordingly, the memory system may determine whether the first conductive path maintains a single conductive path. The memory system may determine whether the memory die includes one or more defects (e.g., cracks) based on whether the first conductive path maintains the single conductive path.

In addition to applicability in memory systems as described herein, techniques for semiconductor die crack detection may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by including a die ring that extends into a memory die (e.g., vertically), which may may inhibit crack propagation for memory dies, which may reduce electronic waste and preserve a life of memory devices. Further, these techniques may allow a manufacturer or user to detect where cracks occur within a memory die, and may adjust a manufacturing process accordingly, which may increase a life of memory devices, among other benefits.

Features of the disclosure are illustrated and described in the context of systems, devices, and circuits. Features of the disclosure are further illustrated and described in the context of a memory die and flowcharts.

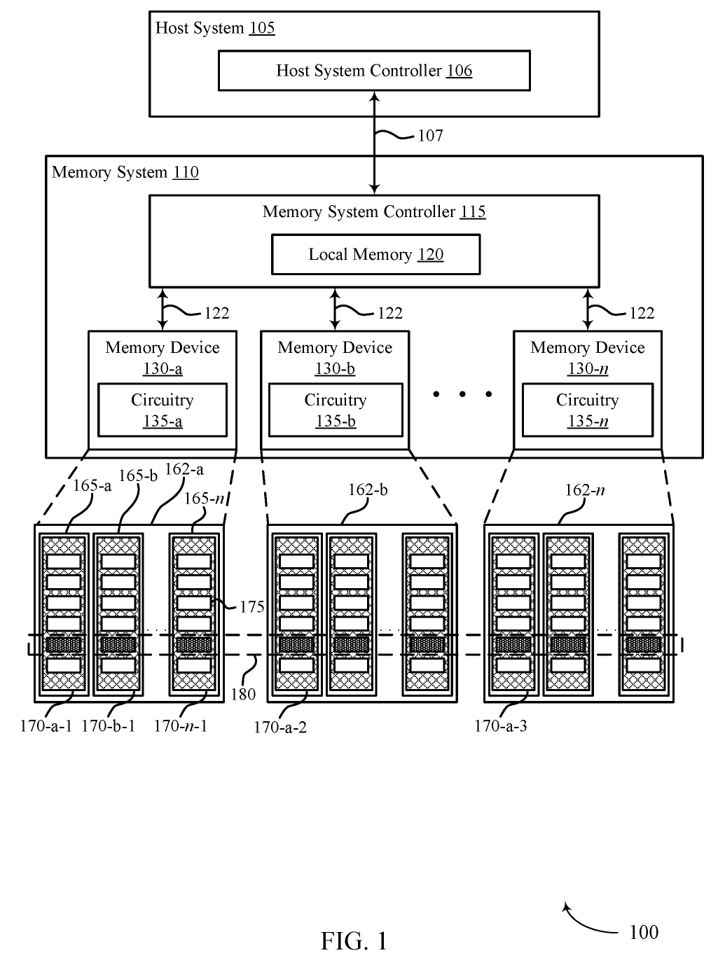

FIG. 1 shows an example of a system 100 that supports semiconductor die crack detection in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface 107 with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via an interface 107. The host system 105 and the memory system 110 may, in some cases, be configured to communicate via the interface 107 using an associated protocol (e.g., to exchange or otherwise communicate control, address, data, and other signals between the memory system 110 and the host system 105). Examples of the interface 107 may include, but are not limited to, a SATA interface, a UFS interface, an eMMC interface, a PCIe interface, a USB interface, a Fiber Channel interface, a SCSI, a Serial Attached SCSI (SAS) interface, a Double Data Rate (DDR) interface, a DIMM interface (e.g., DIMM socket interface that supports DDR), an Open NAND Flash Interface (ONFI), Mobile Industry Processor Interface (MIPI) Unified Protocol (UniPro), MIPI Physical (M-PHY) interface, and a Low Power Double Data Rate (LPDDR) interface. In some examples, multiple such interfaces 107 may be included in or otherwise supported between a host system controller 106 of the host system 105 and a memory system controller 115 of the memory system 110 (e.g., the interface 107 may support communication via multiple protocol layers such as UFS at an application layer, UniPro at a transport layer, and M-PHY at a physical layer).

The memory system 110 may include a memory system controller 115 and one or more memory devices 130. A memory device 130 may include one or more memory arrays of any type of memory cells (e.g., non-volatile memory cells, volatile memory cells, or any combination thereof). The memory system 110 may include memory devices 130-a, 130-b, up to 130-n, where n represents any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the interface 107) and may be an example of a controller or control component configured to cause the memory system 110 to perform various operations in accordance with examples as described herein. The memory system controller 115 may also be coupled with and communicate with memory devices 130 via respective interfaces 122 to perform operations such as reading data, writing data, erasing data, or refreshing data at a memory device 130—among other such operations—which may generically be referred to as access operations. In some examples, the respective interfaces 122 may be examples of single data rate (SDR) interfaces, DRR interfaces, ONFI interfaces, and the like. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include volatile memory (e.g., static random access memory (SRAM), dynamic random access memory (DRAM), or other memory) that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or respective circuitry 135, which may be internal to memory devices 130, respectively, to perform the functions ascribed herein to the memory system controller 115. In general, one or more functions ascribed herein to the memory system controller 115 may, in some cases, be performed instead by the host system 105, circuitry 135, or any combination thereof. For example, the circuitry 135 may be or include a microcontroller, special purpose logic circuitry (e.g., an FPGA, an ASIC, a DSP), or any other suitable processor or processing circuitry. Thus, in some instances, “processor” or “processing circuitry” may refer to functions performed by the memory system controller 115, the host system 105, the circuitry 135 of one or more memory devices 130, or any combination thereof. In some cases, a memory system 110 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as DRAM memory cells or SRAM memory cells.

In some examples, a memory device 130 may include (e.g., on the same die, within the same package) circuitry 135, which may execute or otherwise support operations on one or more memory cells of the respective memory device 130. Respective circuitry 135 may operate in conjunction with a memory system controller 115 or may perform one or more functions ascribed herein to the memory system controller 115. For example, as illustrated in FIG. 1, a memory device 130-a may include circuitry 135-a, a memory device 130-b may include circuitry 135-b, and a memory device 130-n may include circuitry 135-n.

In some cases, a memory device 130 may be or include a NAND device (e.g., NAND flash device). A memory device 130 may be or include a die 162 (e.g., a memory die). For example, in some cases, a memory device 130 may be a package that includes one or more dies 162. A die 162 may, in some examples, be a piece of electronics-grade semiconductor cut from a wafer (e.g., a silicon die cut from a silicon wafer). The memory cells for each die 162 may be arranged in one or more planes 165, and each plane 165 may include one or more blocks 170, where each block 170 may include one or more pages 175, and each page 175 may include a set of memory cells. In some examples, each die 162 may include n planes 165 and each plane may include m blocks 170, where n and m represent positive integers.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, concurrent operations may be performed on different planes 165 or on different blocks 170. For example, concurrent operations may be performed on memory cells within different blocks 170 so long as the different blocks 170 are in different planes 165. In some examples, each memory die 162 may include any quantity of planes 165. For example, the memory die 162-a may include a plane 165-a, a plane 165-b, and a plane 165-n, where n represents an Nth plane. The memory die 162-b and the memory die 162-n may also include N planes. In some cases, an individual block 170 may be referred to as a physical block, and a virtual block 180 may refer to a group of physical blocks 170 within which concurrent operations may occur. A virtual block 180 may be a logical structure that includes a plurality of blocks, where different blocks of the plurality of blocks may come from different planes 165 or different memory dies 162. In some cases, a virtual block may include blocks 170 from different memory devices 130 (e.g., including blocks in one or more planes 165 of memory device 130-a, memory device 130-b, and memory device 130-n). In some examples, a virtual block may include a respective block from each plane 165 (e.g., a block 170 from each plane 165) of one or more memory dies 162.

In some cases, the blocks 170 within a virtual block may have the same block address within their respective planes 165. For example, block 170-a-1 may be “block 0” of a first plane of die 162-a, block 170-a-2 may be “block 0” of a first plane of die 162-b, block 170-a-3 may be “block 0” of a first plane of die 162-n, and so on. By way of further example, block 170-b-1 may be “block 1” of a first plane of die 162-a and block 170-n1 may be “block n” of die 162-a, where n represents an Nth block. The memory die 162-b and the memory die 162-n may also include N blocks. In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). For example, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be restricted from being re-written with new data until they are erased. Thus, for example, an invalid page 175 may, in some cases, not be updated until the entire block 170 that includes the page 175 has been erased.

In some implementations, as described herein the memory system 110 may include a wall of one or more TSVs to form a die crack ring around an edge (e.g., a boundary, a perimeter) of a memory die 162 (e.g., for crack detection and prevention). The memory system 110 may detect crack propagation in the memory die 162 from both a front side and a back side of the memory die 162 (e.g., by measuring electrical opens of a die ring daisy chain structure of the wall of TSVs). For example, a memory system 110 may include a memory die 162, a first conductive path, and control circuitry. The memory die 162 may include an array of memory cells (e.g., a plane 165) at an array portion of the memory die 162. The first conductive path may extend from an upper surface of the memory die 162 past a lower surface of the array portion of the memory die 162 (and, in some cases, to a lower surface of the memory die 162). The memory system 110 (e.g., via the control circuitry) may transmit a first electrical signal via the first conductive path. Accordingly, the memory system 110 may determine whether the first conductive path maintains a single (e.g., continuous) conductive path. The memory system 110 may determine whether the memory die 162 includes one or more defects (e.g., cracks) based on whether the first conductive path maintains the single conductive path. In some cases, these techniques may be applicable to detect defects on (e.g., cracks propagating from) a front side of the memory die 162, at a backside of the memory die 162, or both.

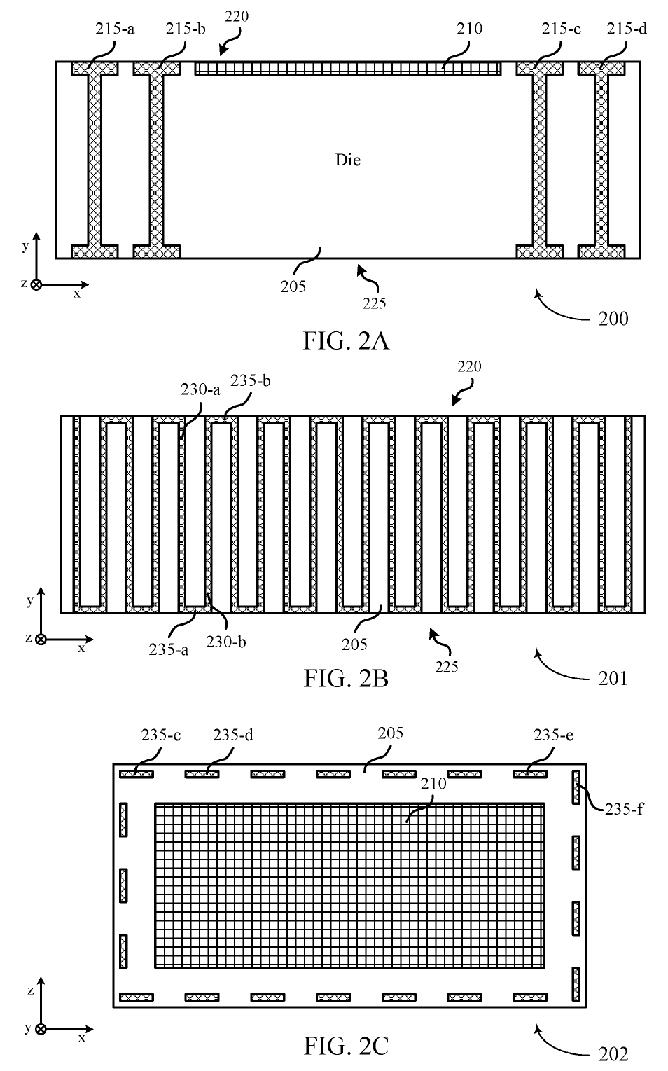

FIGS. 2A-2C illustrate an example of a memory die 205 that supports semiconductor die crack detection in accordance with examples as disclosed herein. For example, FIGS. 2A-2C each illustrate a view (e.g., a perspective view, a cross section view) of a memory die that implements techniques as described herein. In some implementations, the memory die shown in any of FIGS. 2A-2C may be a same memory die (e.g., viewing different portions or cross sections of the same memory die). In the following description, the techniques described in the context of a memory die may also be applied in the context of other semiconductor dies (e.g., an interface die, a wafer). That is, in some cases, as described herein, the term “memory die” may be used for simplicity of understanding, but may equally refer to a semiconductor die (e.g., including an interface portion) or wafer that implements techniques for die crack detection.

As described herein, the term “conductive path” may refer to a conductive material (e.g., a conductive via) through which electrical current may flow. For example, a conductive path may include (or may be made of) copper, titanium, tantalum, other conductive materials, or any combination thereof. The term “die ring” may refer to one or more conductive paths, which may be coupled together. A die ring may be located at or near an edge of a die (e.g., a memory die) and may surround the die at an outer boundary or a perimeter of the die. In some cases, multiple conductive paths may be “daisy-chained” together to form a die ring or a portion thereof. (e.g., as described with reference to FIG. 2B). The term “defects” may refer to aspects of a die that impact (e.g., negatively impact) functions of the die. Such defects may include cracks, dents, fractures, rifts, breaks, or other issues that may affect a die (e.g., disrupting signals in a conductive path, or potentially affecting an array portion of the die).

FIG. 2A shows an example of a cross-sectional view 200 of the memory die 205 that supports semiconductor die crack detection in accordance with examples as disclosed herein. The cross-sectional view 200 illustrates an internal cross section of the memory die 205 (e.g., a center cross section of the memory die 205). As illustrated in the cross-sectional view 200, the memory die 205 (e.g., semiconductor die, interface die) may include an array portion 210 (e.g., a functional array) that includes a set (e.g., an array) of memory cells (e.g., an interface portion that includes interface circuitry). The array portion 210 may be located at a first surface 220 of the memory die 205. In some cases, the array portion 210 may extend into at least a portion of the memory die 205 toward a second surface 225 of the memory die 205.

The memory die 205 may include one or more conductive paths 215, including a first conductive path 215-a (e.g., a continuous conductive path, a first die ring). The first conductive path 215-a may extend, in a first direction (e.g., into the memory die 205 from the first surface 220), from an upper surface of the memory die 205 (e.g., the first surface 220) to a location that is past (e.g., below) a lower surface of the array portion 210. Additionally, or alternatively, the memory die 205 may include a second conductive path 215-b (e.g., a second die ring) that extends, in the first direction, from the upper surface of the memory die 205 to a location that is past (e.g., below) the lower surface of the array portion. The second conductive path 215-b may be coupled with the first conductive path 215-a. As described herein, the terms “upper” and “lower” (e.g., an “upper” surface or a “lower” surface) may be used for clarity. However, these terms may depend on a perspective of an observer. Accordingly, an “upper” surface may be a “lower” surface, a “side” surface, a “front” surface”, a “back” surface, or another surface (and vice versa).

The memory die 205 may include control circuitry. In some cases, a memory system 110 corresponding to the memory die 205 may include the control circuitry. Accordingly, the memory system 110 may be configured to perform the techniques described herein for die crack detection. The control circuitry may be configured to detect one or more defects in the memory die 205 based on a disruption in signaling transmitted via the first conductive path 215-a. For example, the memory system 110 may measure one or more electrical opens in one or more conductive paths 215 (e.g., die ring daisy chain structure) to determine defects in the memory die 205. In some examples, a disruption in signaling transmitted via a conductive path 215 may be based on the conductive path 215 failing to maintain a single (e.g., continuous) conductive path. For example, the control circuitry (e.g., the memory system 110) may detect the one or more defects based on the first conductive path 215-a failing to maintain a continuous conductive path.

In some cases, the control circuitry may be configured to detect the one or more defects in the memory die 205 based on a disruption in signaling transmitted via the first conductive path 215-a and the second conductive path 215-b. In some implementations, the memory system 110 may transmit a first electrical signal via the first conductive path 215-a, via the second conductive path 215-b, or both. The memory system 110 may determine that the memory die 205 includes one or more defects based on a disruption in the first electrical signal transmitted via the first conductive path 215-a, the second conductive path 215-b, or both. In some examples, the memory system 110 may determine that the memory die 205 includes one or more defects based on a measurement (e.g., a quality measurement) of the first electrical signal transmitted via a conductive path 215. For example, if the memory system 110 determines that a quality of the first electrical signal has decreased (e.g., if the conductive path 215 is at least partially broken or severed), the memory system 110 may detect the one or more defects at the memory die 205 (e.g., based on a loss of signal quality of the first electrical signal).

In some cases, the memory die 205 may include a substrate that includes a first material (e.g., a substrate formed of the first material) having a first durability. The array portion 210 and the one or more conductive paths 215 may extend into the substrate. In some examples, the one or more conductive paths 215 (e.g., the first conductive path 215-a) may include (e.g., be formed of) a second material that forms a barrier within the substrate. The second material may have a second durability that is greater than the first durability. Accordingly, the one or more conductive paths 215 may form a barrier to inhibit or prevent defects (e.g., cracks) within the memory die (e.g., preventing defects from reaching the array portion 210). In some cases, the first conductive path 215-a (or another path 215) may be an example of a crack sensor. In some implementations, the first conductive path 215-a may extend from the upper surface (e.g., the first surface 220) of the memory die 205 to a lower surface (e.g., the second surface 225) of the memory die 205 (e.g., as illustrated in the cross-sectional view 200).

In some cases, the memory system 110 may include the memory die 205. Additionally, or alternatively, the memory system 110 may include a semiconductor die that includes an interface portion at a first surface of the semiconductor die. The memory system 110 may further include a second conductive path that extends, in a direction, from an upper surface of the semiconductor die past a lower surface of the interface portion. In some cases, the memory system 110 may include second control circuitry configured to detect one or more defects in the semiconductor die based on a disruption in signaling transmitted via the second conductive path. Accordingly, the techniques described herein may be equally applied to semiconductor dies such as interface dies.

FIG. 2B shows an example of a cross-sectional view 201 of the memory die 205 that supports semiconductor die crack detection in accordance with examples as disclosed herein. The cross-sectional view 201 illustrates an internal cross section of the memory die 205, near an edge of the memory die 205 (e.g., where multiple conductive paths 215 may be seen daisy-chained together). The memory die 205 may include a first set of conductive paths 230. The first conductive paths 230 may be arranged around at least a portion of the perimeter of the memory die 205. Accordingly, the cross-sectional view 201 may be a view of the at least portion of the perimeter.

In some cases, each conductive path 230 of the first set of conductive paths 230 may be coupled with an adjacent conductive path 230 to form the first conductive path 215-a (e.g., a continuous conductive path, as described with reference to FIG. 2A). For example, a conductive path 230-a may be coupled with an adjacent conductive path 230-b via a coupling link 235-a. In some cases, the conductive path 230-a, the coupling link 235-a, and the adjacent conductive path 230-b may be referred to as a single conductive path (e.g., forming the first conductive path 215-a). In some examples, the single conductive path may include additional conductive paths 230 and coupling links 235. For example, the adjacent conductive path 230-b may be coupled with a corresponding adjacent conductive path 230 via a coupling link 235-b. Forming such a conductive path may be referred to as “daisy chaining” conductive paths (e.g., vias) to form a single conductive path (e.g., a die ring, a continuous conductive path). In some cases, the first set of conductive paths 230 may be arranged laterally around the perimeter of the memory die 205.

In some implementations, the memory die 205 may include a second set of conductive paths 230 isolated from the first set of conductive paths 230. Additionally, or alternatively, the second set of conductive paths 230 may be arranged between the first set of conductive paths 230 and the array portion 210. For example, each conductive path 230 of the second plurality of conductive paths 230 may be coupled with an adjacent conductive path 230 to form the second conductive path 215-b (e.g., as described with reference to FIG. 2A). Accordingly, the cross-sectional view 201 may illustrate the first conductive path 215-a (e.g., the first die ring), which may be at or near an edge of the memory die 205 and extending around the perimeter of the memory die. The second conductive path 215-b may be arranged around the perimeter between the first conductive path 215-a and the array portion 210 (e.g., “behind” the first conductive path 215-a in the cross-sectional view 201).

In some implementations, the memory system 110 may transmit a first electrical signal via the first set of conductive paths 230. The memory system 110 may determine that the memory die 205 includes one or more defects based on a disruption in the first electrical signal transmitted via the first set of conductive paths 230. Additionally, or alternatively, the memory system 110 may transmit a second electrical signal via the second set of conductive paths 230. The memory system 110 may determine that the memory die 250 includes the one or more defects based on a disruption in the second electrical signal transmitted via the second set of conductive paths 230.

FIG. 2C shows an example of a cross-sectional view 202 of the memory die 205 that supports semiconductor die crack detection in accordance with examples as disclosed herein. The cross-sectional view 202 illustrates a top cross section of the memory die 205 (e.g., a surface view of the memory die 205). The cross-sectional view 202 may be an example of a view of the first surface 220 of the memory die 205 (e.g., as described with reference to FIGS. 2A and 2B). As described with reference to FIG. 2B, the memory die 205 may include one or more coupling links 235 (which, in some cases, may be seen at the first surface 220 of the memory die 205), which may link together conductive paths 230 that are arranged laterally around a perimeter of the memory die 205.

As illustrated in the cross-sectional view 202, and as described with reference to FIG. 2C, the memory die 205 may include a first set of conductive paths 230 and one or more coupling links 235 arranged around at least a portion of a perimeter the memory die 205. In some cases, the memory die 205 may include a second set of conductive paths 230 and one or more second coupling links 235 arranged around the at least portion of the perimeter between the first set of conductive paths and the array portion 210.

In some implementations, the memory die 205 may include a third set of conductive paths 230 isolated from the first set of conductive paths 230. The thirds set of conductive paths 230 may be arranged laterally around a second portion of the perimeter of the memory die. Each conductive path 230 of the third set of conductive paths 230 may be coupled with an adjacent conductive path 230 to form a third conductive path 215. For example, one or more first coupling links 235 (e.g., a coupling link 235-c, a coupling link 235-d, and so on) may correspond to the first set of conductive paths 230 (e.g., the first conductive path 215-a). The first set of conductive paths 230 may be arranged around a first portion of the perimeter of the memory die 205. Similarly, one or more second coupling links 235 (e.g., a coupling link 235-e, a coupling link 235-f, and so on) may correspond to the third set of conductive paths 230 (e.g., the third conductive path 215), which may be electronically isolated from the first set of conductive paths 230.

The techniques described herein may support determining a location of one or more defects (e.g., cracks) in the memory die 205 based on applying different voltages to one or more sets of conductive paths 230 (e.g., one or more conductive paths 215). For example, a memory system 110 (e.g., control circuitry corresponding to the memory die 205) may be configured to detect a location of the one or more defects in the memory die based on a disruption in signaling transmitted via the first conductive path 215-a, the third conductive path 215, or both. For instance, if there is a disruption in signaling (e.g., a first electrical signal) transmitted via the first conductive path 215-a, the memory system 110 may detect one or more defects at a portion of the perimeter of the memory die 205 corresponding to the first conductive path 215-a. Similarly, if there is a disruption in signaling (e.g., a third electrical signal) transmitted via the third conductive path 215, the memory system 110 may detect one or more defects at a portion of the perimeter of the memory die 205 corresponding to the third conductive path 215. Accordingly, the memory system 110 may detect a location of one or more defects in the memory die 205 based on similar techniques using multiple (e.g., more than two) conductive paths 215 that span respective portions of the perimeter of the memory die 205.

Techniques described herein may provide prevention and detection of die crack propagation into the array portion 210 (e.g., the functional array in a core memory die). These techniques may prevent and detect cracks that begin from any edge of the memory die 205 (e.g., front, back, side). The conductive path structure (e.g., die ring structure) may be tested at a wafer probe corresponding to the memory die 250. Additionally, or alternatively, the memory die 205 may be wafer probe tested on a back side of a wafer (e.g., at post wafer fabrication (PWF) backside finish, PWF backside process). The memory die 205 may similarly be tested post assembly (e.g., at a final package test). Further, the memory system 110 may intercept a crack at the memory die 205 and may stop the crack (e.g., as with a dislocation in a silicon lattice prior to electrical detection).

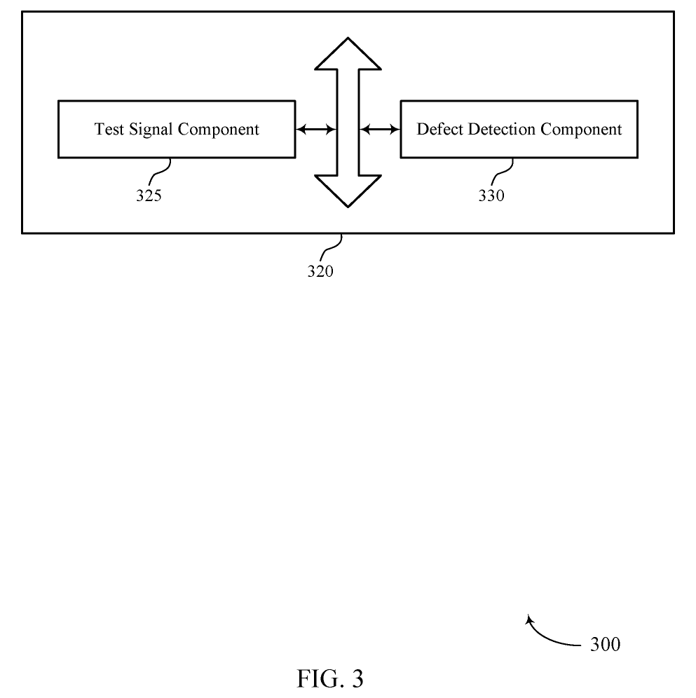

FIG. 3 shows a block diagram 300 of a memory system 320 that supports semiconductor die crack detection in accordance with examples as disclosed herein. The memory system 320 may be an example of aspects of a memory system as described with reference to FIGS. 1-2. The memory system 320, or various components thereof, may be an example of means for performing (e.g., to cause the memory system 320 to perform) various aspects of semiconductor die crack detection as described herein. For example, the memory system 320 may include a test signal component 325 a defect detection component 330, or any combination thereof. Each of these components, or components of subcomponents thereof (e.g., one or more processors, one or more memories), may communicate, directly or indirectly, with one another (e.g., via one or more buses).

The test signal component 325 may be configured as or otherwise support a means for transmitting a first electrical signal via a first conductive path that extends from an upper surface of a memory die past a lower surface of an array portion of the memory die, where the array portion includes a plurality of memory cells. The defect detection component 330 may be configured as or otherwise support a means for determining that the memory die includes one or more defects based at least in part on a disruption in the first electrical signal transmitted via the first conductive path.

In some examples, to support transmitting the first electrical signal, the test signal component 325 may be configured as or otherwise support a means for transmitting the first electrical signal via the first conductive path and a second conductive path that extends from the upper surface of the memory die past a lower surface of the array portion, the second conductive path coupled with the first conductive path. In some examples, to support transmitting the first electrical signal, the defect detection component 330 may be configured as or otherwise support a means for determining that the memory die includes the one or more defects based at least in part on a disruption in the first electrical signal transmitted via the first conductive path and the second conductive path.

In some examples, to support transmitting the first electrical signal, the test signal component 325 may be configured as or otherwise support a means for transmitting the first electrical signal via a first plurality of conductive paths, the first plurality of conductive paths arranged around at least a portion of a perimeter of the memory die, where each conductive path of the first plurality of conductive paths is coupled with an adjacent conductive path to form the first conductive path. In some examples, to support transmitting the first electrical signal, the defect detection component 330 may be configured as or otherwise support a means for determining that the memory die includes the one or more defects based at least in part on a disruption in the first electrical signal transmitted via the first plurality of conductive paths.

In some examples, the test signal component 325 may be configured as or otherwise support a means for transmitting a second electrical signal via a second plurality of conductive paths isolated from the first plurality of conductive paths and arranged between the first plurality of conductive paths and the array portion, where each conductive path of the second plurality of conductive paths is coupled with an adjacent conductive path to form a second conductive path. In some examples, the defect detection component 330 may be configured as or otherwise support a means for determining that the memory die includes the one or more defects based at least in part on a disruption in the second electrical signal transmitted via the second plurality of conductive paths.

In some examples, the first plurality of conductive paths are arranged laterally around the perimeter of the memory die.

In some examples, the test signal component 325 may be configured as or otherwise support a means for transmitting a third electrical signal via a third plurality of conductive paths isolated from the first plurality of conductive paths and arranged laterally around a second portion of the perimeter of the memory die, where each conductive path of the third plurality of conductive paths is coupled with an adjacent conductive path to form a third conductive path. In some examples, the defect detection component 330 may be configured as or otherwise support a means for determining that the memory die includes the one or more defects based at least in part on a disruption in the third electrical signal transmitted via the third plurality of conductive paths.

In some examples, the defect detection component 330 may be configured as or otherwise support a means for detecting a location of the one or more defects in the memory die based at least in part on a disruption in signaling transmitted via the first conductive path, the third conductive path, or both.

In some examples, the first conductive path extends from the upper surface of the memory die to a lower surface of the memory die.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements) that are configured to cause the memory system 320 to perform one or more operations. In some examples, the described functionality of the memory system 320, or various components thereof, may be implemented at least in part by instructions (e.g., stored in memory, non-transitory computer-readable medium) executable by such at least one processor to cause the memory system 320 to perform one or more operations.

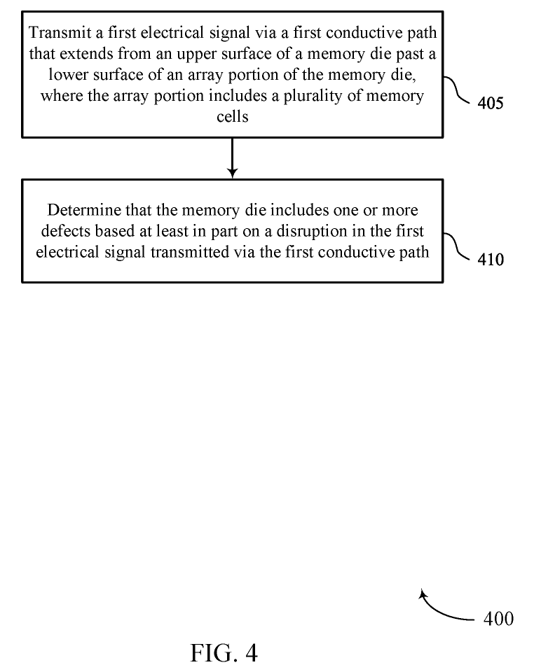

FIG. 4 shows a flowchart illustrating a method 400 that supports semiconductor die crack detection in accordance with examples as disclosed herein. The operations of method 400 may be implemented by a memory system or its components as described herein. For example, the operations of method 400 may be performed by a memory system as described with reference to FIGS. 1-3. In some examples, a memory system may execute a set of instructions to control the functional elements of the device to perform the described functions. Additionally, or alternatively, the memory system may perform aspects of the described functions using special-purpose hardware.

At 405, the method may include transmitting a first electrical signal via a first conductive path that extends from an upper surface of a memory die past a lower surface of an array portion of the memory die, where the array portion includes a plurality of memory cells. In some examples, aspects of the operations of 405 may be performed by a test signal component 325.

At 410, the method may include determining that the memory die includes one or more defects based at least in part on a disruption in the first electrical signal transmitted via the first conductive path. In some examples, aspects of the operations of 410 may be performed by a defect detection component 330.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for transmitting (e.g., communicating) a first electrical signal via a first conductive path that extends from an upper surface of a memory die past a lower surface of an array portion of the memory die, where the array portion includes a plurality of memory cells and determining that the memory die includes one or more defects based at least in part on a disruption (e.g., change) (e.g., a change) in the first electrical signal transmitted via the first conductive path.

Aspect 2: The method, apparatus, or non-transitory computer-readable medium of aspect 1, where transmitting (e.g., communicating) the first electrical signal includes operations, features, circuitry, logic, means, or instructions, or any combination thereof for transmitting (e.g., communicating) the first electrical signal via the first conductive path and a second conductive path that extends from the upper surface of the memory die past a lower surface of the array portion, the second conductive path coupled with the first conductive path and determining that the memory die includes the one or more defects based at least in part on a disruption (e.g., change) in the first electrical signal transmitted (e.g., communicated) via the first conductive path and the second conductive path.

Aspect 3: The method, apparatus, or non-transitory computer-readable medium of any of aspects 1 through 2, where transmitting (e.g., communicating) the first electrical signal includes operations, features, circuitry, logic, means, or instructions, or any combination thereof for transmitting (e.g., communicating) the first electrical signal via a first plurality of conductive paths, the first plurality of conductive paths arranged around at least a portion of a perimeter of the memory die, where each conductive path of the first plurality of conductive paths is coupled with an adjacent conductive path to form the first conductive path and determining that the memory die includes the one or more defects based at least in part on a disruption (e.g., change) in the first electrical signal transmitted (e.g., communicated) via the first plurality of conductive paths.

Aspect 4: The method, apparatus, or non-transitory computer-readable medium of aspect 3, further including operations, features, circuitry, logic, means, or instructions, or any combination thereof for transmitting (e.g., communicating) a second electrical signal via a second plurality of conductive paths isolated from the first plurality of conductive paths and arranged between the first plurality of conductive paths and the array portion, where each conductive path of the second plurality of conductive paths is coupled with an adjacent conductive path to form a second conductive path and determining that the memory die includes the one or more defects based at least in part on a disruption (e.g., change) in the second electrical signal transmitted (e.g., communicated) via the second plurality of conductive paths.

Aspect 5: The method, apparatus, or non-transitory computer-readable medium of any of aspects 3 through 4, where the first plurality of conductive paths are arranged laterally around the perimeter of the memory die.

Aspect 6: The method, apparatus, or non-transitory computer-readable medium of any of aspects 3 through 5, further including operations, features, circuitry, logic, means, or instructions, or any combination thereof for transmitting (e.g., communicating) a third electrical signal via a third plurality of conductive paths isolated from the first plurality of conductive paths and arranged laterally around a second portion of the perimeter of the memory die, where each conductive path of the third plurality of conductive paths is coupled with an adjacent conductive path to form a third conductive path and determining that the memory die includes the one or more defects based at least in part on a disruption (e.g., change) in the third electrical signal transmitted (e.g., communicated) via the third plurality of conductive paths.

Aspect 7: The method, apparatus, or non-transitory computer-readable medium of aspect 6, further including operations, features, circuitry, logic, means, or instructions, or any combination thereof for detecting a location of the one or more defects in the memory die based at least in part on a disruption (e.g., change) in signaling transmitted (e.g., communicated) via the first conductive path, the third conductive path, or both.

Aspect 8: The method, apparatus, or non-transitory computer-readable medium of any of aspects 1 through 7, where the first conductive path extends from the upper surface of the memory die to a lower surface of the memory die.

It should be noted that the described techniques include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: An apparatus, including: a memory die including an array portion that includes a plurality of memory cells; a first conductive path that extends, in a first direction, from an upper surface of the memory die past a lower surface of the array portion; and control circuitry configured to detect one or more defects in the memory die based at least in part on a disruption (e.g., change) in signaling transmitted (e.g., communicated) via the first conductive path.

Aspect 10: The apparatus of aspect 9, further including: a second conductive path that extends, in the first direction, from the upper surface of the memory die past the lower surface of the array portion, the second conductive path coupled with the first conductive path, where the control circuitry is configured to detect the one or more defects in the memory die based at least in part on a disruption (e.g., change) in signaling transmitted (e.g., communicated) via the first conductive path and the second conductive path.

Aspect 11: The apparatus of any of aspects 9 through 10, further including: a first plurality of conductive paths arranged around at least a portion of a perimeter of the memory die, where each conductive path of the first plurality of conductive paths is coupled with an adjacent conductive path to form the first conductive path.

Aspect 12: The apparatus of aspect 11, further including: a second plurality of conductive paths isolated from the first plurality of conductive paths and arranged between the first plurality of conductive paths and the array portion, where each conductive path of the second plurality of conductive paths is coupled with an adjacent conductive path to form a second conductive path.

Aspect 13: The apparatus of any of aspects 11 through 12, where the first plurality of conductive paths are arranged laterally around the perimeter of the memory die.

Aspect 14: The apparatus of any of aspects 11 through 13, further including: a third plurality of conductive paths isolated from the first plurality of conductive paths and arranged laterally around a second portion of the perimeter of the memory die, where each conductive path of the third plurality of conductive paths is coupled with an adjacent conductive path to form a third conductive path.

Aspect 15: The apparatus of aspect 14, where the control circuitry is further configured to: detect a location of the one or more defects in the memory die based at least in part on a disruption (e.g., change) in signaling transmitted (e.g., communicated) via the first conductive path, the third conductive path, or both.

Aspect 16: The apparatus of any of aspects 9 through 15, further including: a substrate including a first material having a first durability, where the first conductive path includes a second material that forms a barrier within the substrate, the second material having a second durability that is greater than the first durability.

Aspect 17: The apparatus of any of aspects 9 through 16, where the first conductive path includes a crack sensor.

Aspect 18: The apparatus of any of aspects 9 through 17, where the first conductive path extends from the upper surface of the memory die to a lower surface of the memory die.

Aspect 19: The apparatus of any of aspects 9 through 18, where the disruption (e.g., change) in signaling transmitted via the first conductive path is based at least in part on the first conductive path failing to maintain a single conductive path.

Aspect 20: The apparatus of any of aspects 9 through 19, further including: a semiconductor die comprising an interface portion at a first surface of the semiconductor die, a second conductive path that extends, in a second direction, from an upper surface of the semiconductor die past a lower surface of the interface portion, and second control circuitry configured to detect one or more defects in the semiconductor die based at least in part on a disruption (e.g., change) in signaling transmitted via the second conductive path.

Aspect 21: An apparatus, including: a semiconductor die including a first portion at a first surface of the semiconductor die; a first conductive path that extends, in a first direction, from an upper surface of the semiconductor die past a lower surface of the first portion; and control circuitry configured to detect one or more defects in the semiconductor die based at least in part on a disruption (e.g., change) in signaling transmitted (e.g., communicated) via the first conductive path.

Aspect 22: The apparatus of aspect 21, where the first portion is an array portion of the semiconductor die.

Aspect 23: The apparatus of any of aspects 21 through 22, where the first portion is an interface portion of the memory die.

Aspect 24: The apparatus of any of aspects 21 through 23, further including: a second conductive path that extends, in the first direction, from the upper surface of the semiconductor die past the lower surface of the first portion, the second conductive path coupled with the first conductive path, where the control circuitry is configured to detect the one or more defects in the semiconductor die based at least in part on a disruption in signaling transmitted via the first conductive path and the second conductive path.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor’s threshold voltage is applied to the transistor gate. The transistor may be “off” or “deactivated” if a voltage less than the transistor’s threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
a memory die comprising an array portion that includes a plurality of memory cells;
a first conductive path that extends, in a first direction, from an upper surface of the memory die past a lower surface of the array portion; and
control circuitry configured to detect one or more defects in the memory die based at least in part on a disruption in signaling transmitted via the first conductive path.

2. The apparatus of claim 1, further comprising:
a second conductive path that extends, in the first direction, from the upper surface of the memory die past the lower surface of the array portion, the second conductive path coupled with the first conductive path, wherein the control circuitry is configured to detect the one or more defects in the memory die based at least in part on a disruption in signaling transmitted via the first conductive path and the second conductive path.

3. The apparatus of claim 1, further comprising:
a first plurality of conductive paths arranged around at least a portion of a perimeter of the memory die, wherein each conductive path of the first plurality of conductive paths is coupled with an adjacent conductive path to form the first conductive path.

4. The apparatus of claim 3, further comprising:
a second plurality of conductive paths isolated from the first plurality of conductive paths and arranged between the first plurality of conductive paths and the array portion, wherein each conductive path of the second plurality of conductive paths is coupled with an adjacent conductive path to form a second conductive path.

5. The apparatus of claim 3, wherein the first plurality of conductive paths are arranged laterally around the perimeter of the memory die.

6. The apparatus of claim 3, further comprising:
a third plurality of conductive paths isolated from the first plurality of conductive paths and arranged laterally around a second portion of the perimeter of the memory die, wherein each conductive path of the third plurality of conductive paths is coupled with an adjacent conductive path to form a third conductive path.

7. The apparatus of claim 6, wherein the control circuitry is further configured to:
detect a location of the one or more defects in the memory die based at least in part on a disruption in signaling transmitted via the first conductive path, the third conductive path, or both.

8. The apparatus of claim 1, further comprising:
a substrate comprising a first material having a first durability, wherein the first conductive path comprises a second material that forms a barrier within the substrate, the second material having a second durability that is greater than the first durability.

9. The apparatus of claim 1, wherein the first conductive path extends from the upper surface of the memory die to a lower surface of the memory die.

10. The apparatus of claim 1, wherein the disruption in signaling transmitted via the first conductive path is based at least in part on the first conductive path failing to maintain a single conductive path.

11. The apparatus of claim 1, further comprising:
a semiconductor die comprising an interface portion at a first surface of the semiconductor die;
a second conductive path that extends, in a second direction, from an upper surface of the semiconductor die past a lower surface of the interface portion; and
second control circuitry configured to detect one or more defects in the semiconductor die based at least in part on a disruption in signaling transmitted via the second conductive path.

12. A memory system, comprising:
one or more memory devices; and
processing circuitry coupled with the one or more memory devices and configured to cause the memory system to:
transmit a first electrical signal via a first conductive path that extends from an upper surface of a memory die past a lower surface of an array portion of the memory die, wherein the array portion comprises a plurality of memory cells; and
determine that the memory die comprises one or more defects based at least in part on a disruption in the first electrical signal transmitted via the first conductive path.

13. The memory system of claim 12, wherein, to transmit the first electrical signal, the processing circuitry is configured to cause the memory system to:
transmit the first electrical signal via the first conductive path and a second conductive path that extends from the upper surface of the memory die past a lower surface of the array portion, the second conductive path coupled with the first conductive path; and
determine that the memory die comprises the one or more defects based at least in part on a disruption in the first electrical signal transmitted via the first conductive path and the second conductive path.

14. The memory system of claim 12, wherein, to transmit the first electrical signal, the processing circuitry is configured to cause the memory system to:
transmit the first electrical signal via a first plurality of conductive paths, the first plurality of conductive paths arranged around at least a portion of a perimeter of the memory die, wherein each conductive path of the first plurality of conductive paths is coupled with an adjacent conductive path to form the first conductive path; and
determine that the memory die comprises the one or more defects based at least in part on a disruption in the first electrical signal transmitted via the first plurality of conductive paths.

15. The memory system of claim 14, wherein the processing circuitry is further configured to cause the memory system to:
transmit a second electrical signal via a second plurality of conductive paths isolated from the first plurality of conductive paths and arranged between the first plurality of conductive paths and the array portion, wherein each conductive path of the second plurality of conductive paths is coupled with an adjacent conductive path to form a second conductive path; and
determine that the memory die comprises the one or more defects based at least in part on a disruption in the second electrical signal transmitted via the second plurality of conductive paths.

16. The memory system of claim 14, wherein the processing circuitry is further configured to cause the memory system to:
transmit a third electrical signal via a third plurality of conductive paths isolated from the first plurality of conductive paths and arranged laterally around a second portion of the perimeter of the memory die, wherein each conductive path of the third plurality of conductive paths is coupled with an adjacent conductive path to form a third conductive path; and
determine that the memory die comprises the one or more defects based at least in part on a disruption in the third electrical signal transmitted via the third plurality of conductive paths.

17. The memory system of claim 16, wherein the processing circuitry is further configured to cause the memory system to:
detect a location of the one or more defects in the memory die based at least in part on a disruption in signaling transmitted via the first conductive path, the third conductive path, or both.

18. The memory system of claim 12, wherein the first conductive path extends from the upper surface of the memory die to a lower surface of the memory die.

19. A method by a memory system, comprising:
communicating a first electrical signal via a first conductive path that extends from an upper surface of a memory die past a lower surface of an array portion of the memory die, wherein the array portion comprises a plurality of memory cells; and
determining that the memory die comprises one or more defects based at least in part on a change in the first electrical signal transmitted via the first conductive path.

20. The method of claim 19, wherein communicating the first electrical signal comprises:
communicating the first electrical signal via the first conductive path and a second conductive path that extends from the upper surface of the memory die past a lower surface of the array portion, the second conductive path coupled with the first conductive path; and
determining that the memory die comprises the one or more defects based at least in part on a change in the first electrical signal transmitted via the first conductive path and the second conductive path.

21. The method of claim 19, wherein communicating the first electrical signal comprises:
communicating the first electrical signal via a first plurality of conductive paths, the first plurality of conductive paths arranged around at least a portion of a perimeter of the memory die, wherein each conductive path of the first plurality of conductive paths is coupled with an adjacent conductive path to form the first conductive path; and
determining that the memory die comprises the one or more defects based at least in part on a change in the first electrical signal transmitted via the first plurality of conductive paths.

22. An apparatus, comprising:
a semiconductor die comprising a first portion at a first surface of the semiconductor die;
a first conductive path that extends, in a first direction, from an upper surface of the semiconductor die past a lower surface of the first portion; and
control circuitry configured to detect one or more defects in the semiconductor die based at least in part on a disruption in signaling transmitted via the first conductive path.

23. The apparatus of claim 22, wherein the first portion comprises an array portion of the semiconductor die.

24. The apparatus of claim 22, wherein the first portion comprises an interface portion of the semiconductor die.

25. The apparatus of claim 22, further comprising:
a second conductive path that extends, in the first direction, from the upper surface of the semiconductor die past the lower surface of the first portion, the second
conductive path coupled with the first conductive path, wherein the control circuitry is configured to detect the one or more defects in the semiconductor die based at least in part on a disruption in signaling transmitted via the first conductive path and the second conductive path.
